(19) United States
(12) Patent Application Publication
(10) Pub. No.: US 2026/0044070 A1
(43) Pub. Date: Feb. 12, 2026

(54) METHOD OF REPAIRING PHOTOMASK

(71) Applicant: Samsung Electronics Co., Ltd., Suwon-si (KR)

(72) Inventors: Junki Kim, Suwon-si (KR); Jiwoo Park, Suwon-si (KR); Sanghyeon Lee, Suwon-si (KR); Jimin Lim, Suwon-si (KR)

(21) Appl. No.: 19/290,610

(22) Filed: Aug. 5, 2025

(30) Foreign Application Priority Data
Aug. 6, 2024 (KR) 10-2024-0104728

(51) Int. Cl. G03F 1/74; G03F 1/54; G03F 1/80

(52) U.S. Cl. CPC G03F 1/74; G03F 1/80; G03F 1/54

(57) ABSTRACT

A method of repairing a photomask includes performing Si pre-treatment on an absorber layer having a defect and performing absorber defect etching by using an etching gas. The method may further include alternately performing the absorber defect etching by using an etching gas and Si mid-treatment on the absorber layer such that a total time of the absorber defect etching is 2 times to 10 times and each Si mid-treatment on the absorber layer is performed between two consecutive absorber defect etchings. The method may further include performing Si post-treatment on the absorber layer after a last time the absorber defect etching is performed.

### CROSS-REFERENCE TO RELATED APPLICATION

This application is based on and claims priority under 35 U.S.C. § 119 to Korean Patent Application No. 10-2024-0104728, filed on Aug. 6, 2024, in the Korean Intellectual Property Office, the disclosure of which is incorporated by reference herein in its entirety.

### BACKGROUND

The inventive concept relates to a method of repairing a photomask, and more particularly, to a method of repairing an extreme ultraviolet phase shift mask (EUV PSM).

According to lightweight and high performance of electronic devices, miniaturization and high performance have been required in the semiconductor industry. To implement the miniaturization, lightweight, low power consumption, high performance, large capacity, and high reliability of semiconductor, the sizes of patterns formed on a semiconductor substrate have been gradually reduced, and the wavelengths of light sources used in lithography processes have been shortened. Accordingly, introduction of extreme ultraviolet phase shift masks (EUV PSM) is very important for refinement of semiconductor processes. In addition, as materials and structures used to implement refinement of photomask critical dimension (CD) have diversified, e-beam repair technology for repairing defects caused therefrom needs to be advanced accordingly.

The information described above may be provided as related art to facilitate the understanding of the inventive concept. However, the foregoing statements should not be regarded as prior art with respect to the present application.

### SUMMARY

According to an aspect of the inventive concept, there is provided a method of repairing a photomask, the method including performing silicon (Si) pre-treatment on an absorber layer having a defect and performing absorber defect etching by using an etching gas.

The performing of the Si pre-treatment on the absorber layer may include injecting a precursor gas of a Si-based inorganic compound into a repair chamber and adsorbing molecules of the precursor gas of the Si-based inorganic compound onto the absorber layer.

The Si-based inorganic compound may include, for example, at least one of tetraethyl orthosilicate (TEOS), tetramethyl orthosilicate (TMOS), tetrachlorosilane (SiCl₄), trichlorosilane (SiHCl₃), dichlorosilane (SiH₂Cl₂), monochlorosilane (SiH₃Cl), silane (SiH₄), and disilane (Si₂H₆).

The performing of the absorber defect etching by using an etching gas may include injecting the etching gas into the repair chamber and radiating an e-beam to the defect of the absorber layer.

The etching gas may cause depletion reaction with Si-based inorganic compound of a Si pre-treated surface of the absorber layer. The etching gas may include at least one of a fluorine (F)-based etching gas, a chlorine (Cl)-based etching gas, a bromine (Br)-based etching gas, and an iodine (I)-based etching gas.

The e-beam may be greater than 0 keV and less than or equal to 2 keV.

The method may further include performing Si post-treatment on the absorber layer after the absorber defect etching is performed.

The method may further include alternately performing the absorber defect etching by using an etching gas and Si mid-treatment on the absorber layer such that the total number of the absorber defect etching is 2 to 10 times and each Si mid-treatment is performed between two consecutive absorber defect etchings.

The performing of the Si mid-treatment on the absorber layer may include injecting a precursor gas of a Si-based inorganic compound into a repair chamber and adsorbing molecules of the precursor gas of the Si-based inorganic compound onto the absorber layer.

The method may further include performing Si post-treatment on the absorber layer after a last time the absorber defect etching is performed.

The performing of the Si post-treatment on the absorber layer may include injecting a precursor gas of a Si-based inorganic compound into the repair chamber and adsorbing molecules of the precursor gas of the Si-based inorganic compound onto the absorber layer.

The photomask may include a substrate, a reflective layer, a capping layer, and an absorber layer which are sequentially stacked.

The substrate may include a low thermal expansion material (LTEM).

The reflective layer may include a multi-layer structure in which molybdenum (Mo) and silicon (Si) are alternately stacked or a multi-layer structure in which molybdenum (Mo) and beryllium (Be) are alternately stacked, wherein the multi-layer structure may include 2 to 100 layers.

The capping layer may include at least one of ruthenium (Ru), ruthenium silicide, chrome (Cr), chrome oxide, chrome nitride, silicon oxide, and silicon nitride.

The absorber layer may include ruthenium (Ru), platinum (Pt), palladium (Pd), iridium (Ir), rhodium (Rh), osmium (Os), tantalum (Ta), tungsten (W), chrome (Cr), silicon (Si), molybdenum (Mo), nickel (Ni), copper (Cu), titanium (Ti), cobalt (Co), gold (Au), an alloy thereof, or a combination thereof.

The photomask may be an extreme ultraviolet phase shift mask (EUV PSM).

According to another aspect of the inventive concept, there is provided a method of repairing a photomask, the method including alternately performing absorber defect etching by using an etching gas and Si mid-treatment on the absorber layer such that the number of absorber defect etching is 2 to 10 times and each Si mid-treatment is performed between two consecutive absorber defect etching. The photomask may include an absorber layer having at least one defect.

The method may further include performing Si post-treatment on the absorber layer after a last time the absorber defect etching is performed.

According to another aspect of the inventive concept, there is provided a method of repairing a photomask, the method including performing absorber defect etching by using an etching gas, and performing Si post-treatment on the absorber layer. The photomask may include an absorber layer having at least one defect.

### BRIEF DESCRIPTION OF THE DRAWINGS

Embodiments will be more clearly understood from the following detailed description taken in conjunction with the accompanying drawings in which:

FIGS. 1 and 2 are each a cross-sectional view of a photomask used in a method of repairing a photomask according to an embodiment;

FIG. 3 is a cross-sectional view of a photomask having a defect and a normal pattern and used in an embodiment;

FIG. 4 is a diagram illustrating gas damage generated in a process of performing absorber defect etching in an existing method of repairing a photomask;

FIG. 5A is a diagram illustrating a process of performing Si treatment by using tetraethyl orthosilicate (TEOS) in a method of repairing a photomask, according to an embodiment;

FIG. 5B is a diagram illustrating a process of performing absorber defect etching after Si treatment in a method of repairing a photomask, according to an embodiment;

FIGS. 6A and 6B are each a flowchart illustrating a method of repairing a photomask including performing Si pre-treatment on an absorber layer, according to an embodiment;

FIG. 7 is a flowchart illustrating a method of repairing a photomask including performing Si pre-treatment and Si mid-treatment on an absorber layer, according to an embodiment;

FIGS. 8A and 8B are each a flowchart illustrating a method of repairing a photomask including performing Si pre-treatment, Si mid-treatment, and Si post-treatment on an absorber layer, according to an embodiment;

FIG. 9 is a flowchart illustrating a method of repairing a photomask including performing Si mid-treatment on an absorber layer, according to an embodiment;

FIG. 10 is a flowchart illustrating a method of repairing a photomask including performing Si mid-treatment and Si post-treatment on an absorber layer, according to an embodiment;

FIG. 11 is a flowchart illustrating a method of repairing a photomask including performing Si post-treatment on an absorber layer, according to an embodiment;

FIG. 12 is a diagram illustrating the principle of technology of repairing a photomask by using an e-beam;

FIGS. 13A and 13B are each a diagram illustrating a wafer critical dimension (CD) uniformity map when a method of repairing a photomask is performed without Si treatment;

FIG. 14A is a diagram illustrating results of CD uniformity inspection before release of a photomask repaired by a method of repairing a photomask including performing Si pre-treatment, according to an embodiment; and

FIG. 14B is a diagram illustrating results of CD uniformity inspection before release of a photomask repaired by a method of repairing a photomask without performing Si treatment.

### DETAILED DESCRIPTION OF THE EMBODIMENTS

Hereinafter, embodiments of the inventive concept are described in detail with reference to the attached drawings. In describing the embodiments in relation to the drawings, like reference numerals denote like elements, and any redundant description thereof may be omitted.

The terms used here are merely for description of embodiment and are not intended to limit the inventive concept. Expressions used in singular forms encompass plural elements, unless the expressions have clearly different meanings in the context. For example, when a description states that an embodiment includes one element, a plurality of the same elements may be present in the corresponding embodiment. Further, the terms such as “include” or “have” in various embodiments of the disclosure are used to specify the existence of features, numbers, processes, operations, components, parts recited in the detailed description, or combinations thereof, and thus should not be understood as precluding the existence or possibility for addition of one or more other features, numbers, processes, operations, components, parts, or combinations thereof.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Unless otherwise defined, all terms used herein, including technical or scientific terms, may have the same meaning as commonly understood by one of ordinary skill in the art. The terms which are defined in a commonly used dictionary should be construed as having a meaning that matches its contextual meaning in a related art and should not be translated in an ideal or extremely formal sense unless otherwise clearly defined in the embodiments.

In describing the embodiments in relation to the drawings, like reference numerals denote like elements, and any redundant description thereof may be omitted. In the description of embodiments certain detailed explanations of the related art are omitted when it is deemed that they may unnecessarily obscure the essence of the inventive concept.

In addition, such terms as “first,” “second,” “A,” “B,” “(a),” “(b),” etc. may be used to described components of the embodiment. These terms are used only to distinguish one component form another, and the nature, order, etc. of components are not limited by the terms. When a component is described as being “coupled,” “combined,” or “connected” with another component, the component may be directly coupled or connected with another component, or other components may be “coupled,”“combined,”or “connected”therebetween.

Components having common functions are described by using the same term in the embodiments. Unless otherwise described, description provided in an embodiment may be applicable in other embodiments, and any redundant description may be omitted.

The term “about” is used to indicate a numerical range that may be considered by a person skilled in the art to achieve the same function or results. When the term “about” is used with numbers or values, the term “about” may cover ±20 %, ±10 %, ±5 %, or ±2 % of the number or value. In some aspects, the term “about”may indicate the number or the value itself.

Throughout the specification, such expressions as “A or B,” “at least one of A and B,” “at least one of A or B,” “A, B, or C,” “at least one of A, B, and C,” and “at least one of A, B, or C” may each include at least one of listed items or any possible combinations thereof.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

### Photomask

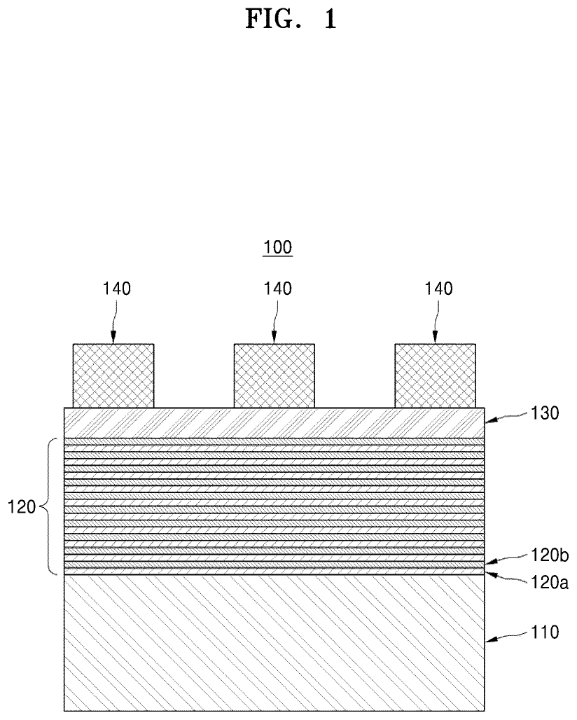

FIGS. 1 to 3 are each a cross-sectional view of a photomask used in a method of repairing a photomask according to an embodiment.

A photomask is an optical device including light-blocking patterns on a substrate to selectively expose a photoresist film applied on a semiconductor substrate to light.

Referring to FIG. 1, a photomask 100 may include a substrate 110, a reflective layer 120, a capping layer 130, and an absorber layer 140. For example, the photomask 100 may have a structure in which the reflective layer 120 is stacked on the substrate 110, the capping layer 130 is stacked on the reflective layer 120, and the absorber layer 140 is stacked on the capping layer 130.

The substrate 110 may be a part constituting a base structure of the photomask 100, and various layers are stacked on the substrate 110 to form the photomask 100. The substrate 110 may include a low thermal expansion material (LTEM). The LTEM refers to a material which has a low thermal expansion coefficient and thus has a small physical size change according to a temperature change, etc., and the thermal expansion coefficient may be, for example, 5×10⁻⁶/° C. or less. However, the inventive concept is not limited thereto. When the photomask 100 is formed by using an LTEM, the formed photomask 100 may have physical stability, and high-precision pattern transfer may be facilitated, e.g., in a photolithography process. Constituent material of the substrate 110 may include or may be titanium oxide, doped silica, quartz, etc. However, this is just an example, and constituent materials of the substrate 110 are not limited thereto. To secure the mechanical strength and the thermal stability of the formed photomask 100, the thickness of the substrate 110 may be about 0.5 mm to about 10 mm; however, the inventive concept is not limited thereto.

The reflective layer 120 may be formed on the substrate 110 and may reflect an extreme ultraviolet (EUV) light coming from a light source to accurately transfer patterns to a photoresist. The reflective layer 120 may include molybdenum (Mo) silicon (Si) or may include Mo and beryllium (Be). The reflective layer 120 may have a multi-layer structure including 2 to 100 layers, e.g., 20 to 70 layers, and in this case, a Mo layer 120a and a Si layer 120b are alternately stacked, or a Mo layer (not shown) and a Be layer (not shown) are alternately stacked.

When the Mo layer 120a and the Si layer 120b are alternately stacked, the thickness of the Mo layer 120a may be about 2.8 nm, and the thickness of the Si layer 120b may be about 4.1 nm to achieve maximum reflection of the EUV light source having a wavelength of about 13.5 nm. When the Mo layer and the Be layer are alternately stacked, the thickness of the Mo layer may be about 2.0 nm, and the thickness of the Be layer may be about 3.5 nm to achieve the maximum reflection of The EUV light source. As such, according to the composition of the reflective layer 120, the proper thickness of a single layer constituting the multi-layer structure may vary, and a person skilled in the art could adjust the thickness of the finally formed reflective layer 120 by properly adjusting the composition and the stacking number of layers in the reflective layer 120.

The capping layer 130 may be formed on the reflective layer 120. The capping layer 130 may prevent damage of the reflective layer 120 that may be caused by an external environment and maintain proper performance of the reflective layer 120. Moreover, the capping layer 130 may prevent oxidation of the reflective layer 120 and minimize a surface defect. The capping layer 130 may include ruthenium (Ru), ruthenium silicide (RuSi), chrome (Cr), chrome oxide, chrome nitride, silicon oxide, silicon nitride, etc. ; however, the inventive concept is not limited thereto. The thickness of the capping layer 130 may be about 2 nm to about 10 nm or about 2 nm to about 5 nm and may be properly adjusted by a person skilled in the art such to sufficiently protect the reflective layer 120 and maintain an optimal reflectivity.

The absorber layer 140 may be formed on the capping layer 130. The absorber layer 140 may be a layer absorbing light and may be patterned such that the absorber layer 140 includes an area that absorbs light and an area that does not absorb light. For example, the absorber layer 140 may include patterns formed of light absorbing layer such that light is absorbed in an area where the light absorbing layer remains and light is not absorbed in an area where the light absorbing layer does not remain. Accordingly, in the light exposure process, a semiconductor wafer may have an unexposed area corresponding to the remaining light absorbing layer of the absorber layer 140 where the light coming from the light source is blocked, and ultimately, a desired pattern may be formed on a semiconductor wafer. The absorber layer 140 may include platinum metals (platinum group metals). As platinum metals have a high absorption rate with respect to an EUV wavelength, on a photomask, unnecessary reflection may be minimized, and a desired pattern may be accurately formed on the semiconductor wafer. In addition, due to high corrosion resistance and chemical stability, platinum metals may remain stable in processes using various chemical materials in the EUV lithography process, which leads to longer lifespan of a mask. Accordingly, the absorber layer 140 may include ruthenium (Ru), platinum (Pt), palladium (Pd), iridium (Ir), rhodium (Rh), osmium (Os), tantalum (Ta), tungsten (W), chrome (Cr), silicon (Si), molybdenum (Mo), nickel (Ni), copper (Cu), titanium (Ti), cobalt (Co), gold (Au), an alloy thereof, or a combination thereof; for example, the absorber layer 140 may include, for example ruthenium (Ru) or an alloy thereof.

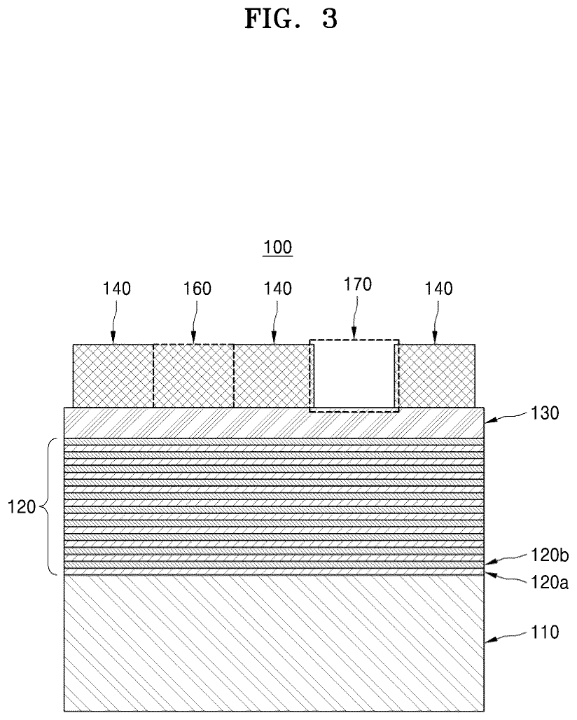

Considering the functionality of the photomask 100, the absorber layer 140 may only include normal patterns 170 without a defect 160; however, as illustrated in FIG. 3, the photomask 100 used in the method of repairing a photomask according to an embodiment may include at least one defect 160. The thickness of the absorber layer 140 may be, for example, about 20 nm to about 100 nm or about 40 nm to about 80 nm; however, the inventive concept is not limited thereto. Defects 160 throughout the present disclosure may be remaining patterns of the absorber layer 140 such that the defects 160 need to be removed to repair the defects 160 or to repair patterns of the absorber layer 140.

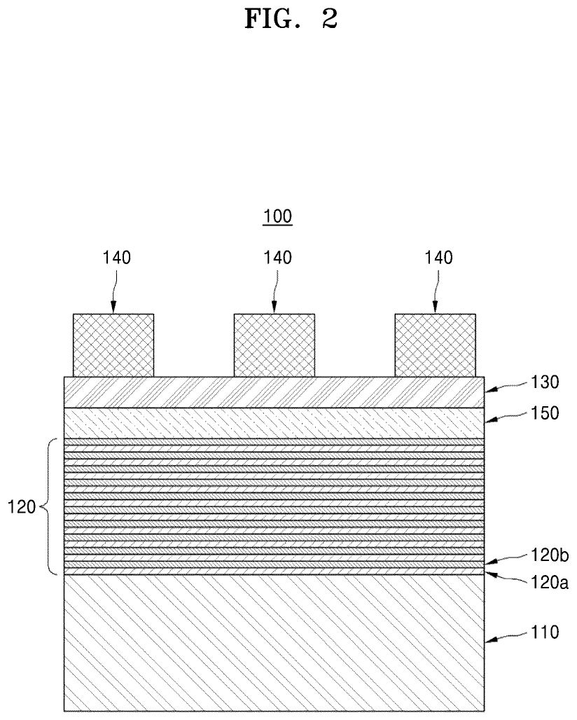

The photomask 100 may include at least one buffer layer 150 in certain embodiments in addition to the substrate 110, the reflective layer 120, the capping layer 130, and the absorber layer 140 described above. The buffer layer 150 may be a layer which may provide physical or chemical protection, improvement in adhesive strength, stress relation, etc. between layers such as the reflective layer 120, the capping layer 130, the absorber layer 140, etc. Referring to FIG. 2, in an embodiment, the buffer layer 150 may be arranged between the reflective layer 120 and the capping layer 130; however, the position of the buffer layer 150 is not limited thereto, and the buffer layer 150 may be arranged between the substrate 110 and the reflective layer 120, between the capping layer 130 and the absorber layer 140, and/or on the absorber layer 140.

### Method of Repairing a Photomask

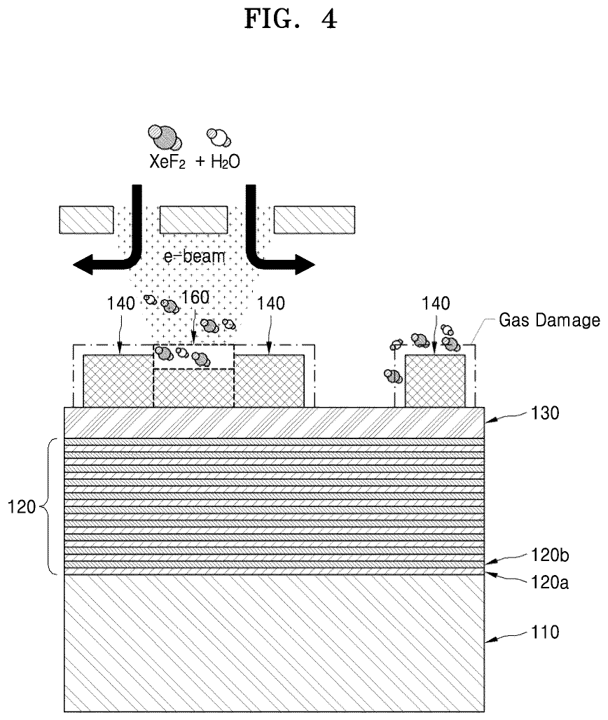

FIG. 4 is a diagram schematically illustrating an existing EUV PSM repairing process. Referring to FIG. 4 in the EUV PSM repairing method, for etching of a defect 160, an etching gas such as xenon difluoride (XeF₂) may be injected into a repair chamber, and then an e-beam may be radiated to the defect 160 for etching the defect 160. In this process, a part of the absorber layer 140, which is not the defect 160, may be damaged and deteriorated by the etching gas injected into the repair chamber, for example, XeF₂, etc. To describe this more specifically with an example, when the absorber layer 140 of the photomask 100 includes ruthenium (Ru), the etching gas such as XeF₂ injected into the repair chamber may reach a surface of the absorber layer 140 and then dissociated into Xe and F. In this case, ruthenium (Ru) may form ruthenium fluoride through fluoridation reaction with F. That is, the surface of the absorber layer 140 that includes ruthenium (Ru) may be changed into ruthenium fluoride, etc. having different chemical and electrical characteristics from ruthenium (R), and as a result, the absorber layer 140 of the photomask may be deteriorated.

In the method of repairing the photomask 100 according to an embodiment, to easily reduce such deterioration, Si pre-treatment may be performed on the absorber layer 140.

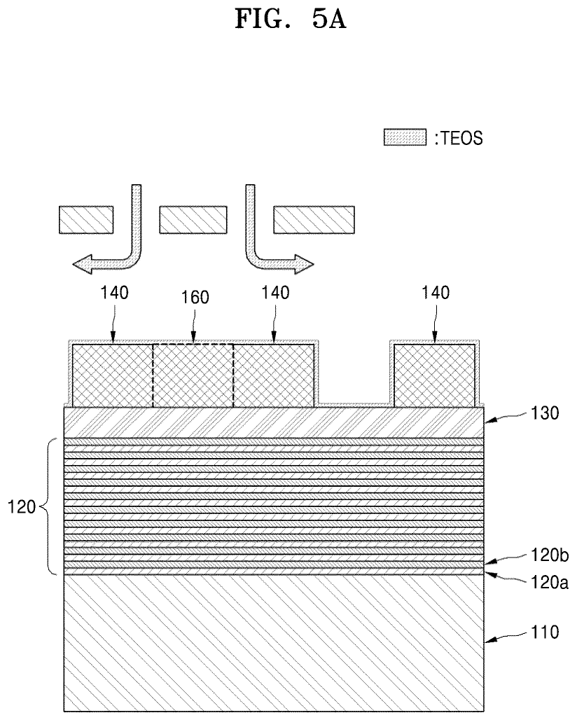

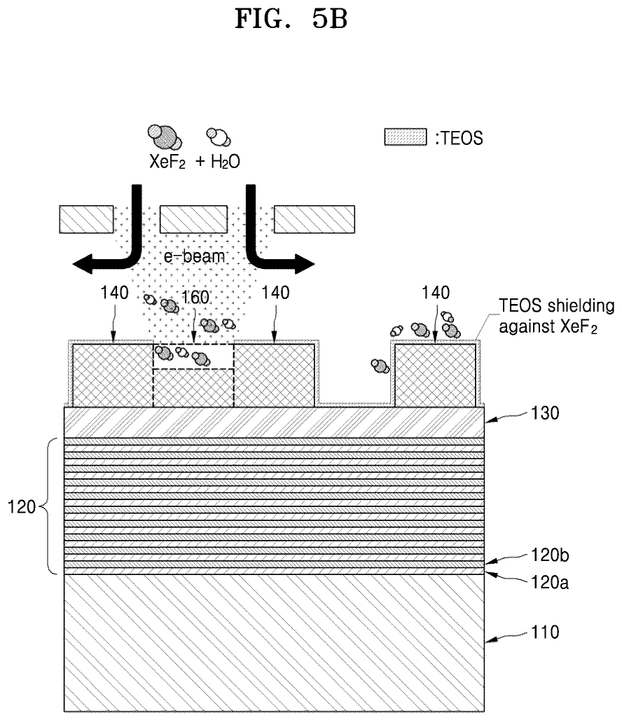

FIG. 5A is a diagram illustrating performance of Si-treatment by using tetraethyl orthosilicate (TEOS), and FIG. 5B is a diagram illustrating performance of absorber defect etching after Si-treatment.

Referring to FIG. 5A, the absorber layer 140 may include a defect 160 on which the absorber defect etching is to be performed, and by injecting a Si-based inorganic compound precursor gas, such as TEOS, into the repair chamber, molecules of the gas may be adsorbed onto the surface of the absorber layer 140. For example, molecules of the gas may be adsorbed onto the surface of the absorber layer 140, which includes ruthenium (Ru) etc., by Van der Waals Forces, etc. As such adsorption is not chemical bonding by chemical reaction, which leads for formation of a rigid layer on the surface of the absorber layer 140, the adsorbed TEOS may be easily separated from the absorber layer 140 by simply changing ambient gas environment without a separate process of removing the TEOS layer after the absorber defect etching to be performed thereafter.

Referring to FIG. 5B, areas of the absorber layer 140 that are not the defect 160 may not be deteriorated due to the shielding effect of the TEOS injected into the repair chamber, and only the defect 160 may be etched by using the etching gas (XeF2) and the e-beam. As mentioned above, the etching gas such as XeF₂, etc. may react with the surface of the absorber layer 140, which includes ruthenium (Ru), and may cause deterioration of the absorber layer 140 when the above mentioned Si-treatment is not performed; however, when the Si-treatment is performed on the absorber layer 140 by using a Si-based inorganic compound precursor gas such as TEOS, the TEOS (Si(OC₂H₅)₄) may react with F of XeF2 to form fluorosilane (FSi(OC₂H₅)₃, F₂Si(OC₂H₅)₂, F₃Si(OC₂H₅), SiF₄). For example, through the depletion reaction between the TEOS and the etching gas (XeF₂), the chemical reaction between the etching gas and the absorber layer 140 may be suppressed.

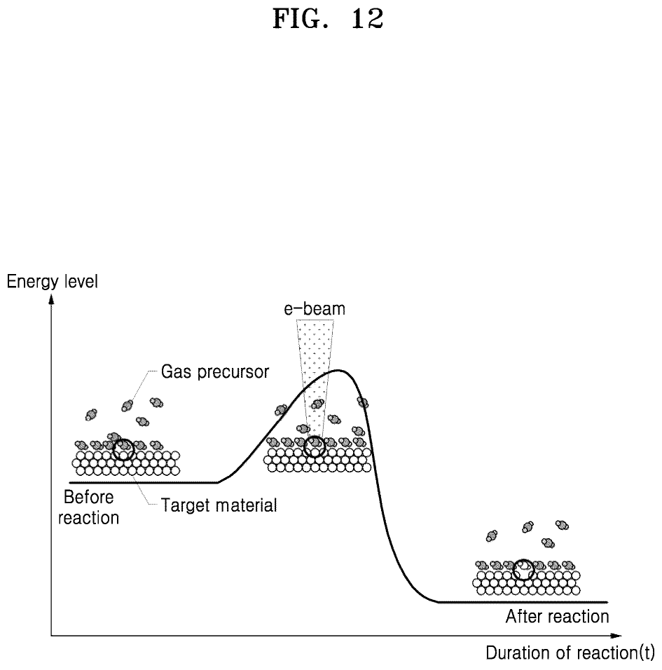

Referring to FIG. 5A, through the Si pre-treatment, a Si-based inorganic compound precursor gas such as TEOS may be adsorbed onto the surface of the defect 160. However, as illustrated in FIG. 12, unlike the areas of the absorber layer 140 other than the defect 160, by radiating an e-beam onto the defect 160 (thereby increasing the energy level of the absorber layer 140 at the defect 160), chemical reaction may occur at the defect 160. Accordingly, as the reactivity of the absorber layer 140 due to the radiation of the e-beam has more impact on the defect 160 than the shielding effect by the Si treatment, selective etching effect to the defect 160 may be achieved, and deterioration of areas other than the defect 160 may be prevented. In this regard, the energy level of the e-beam radiated onto the defect 160 may be, for example, greater than 0 keV and less than or equal to 2 keV.

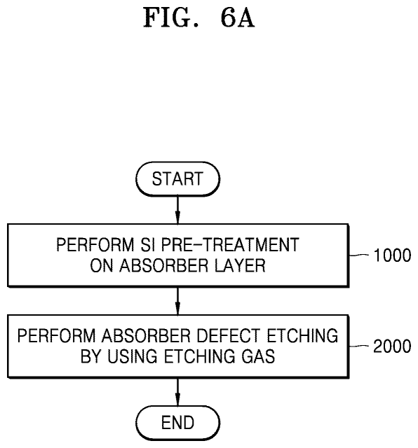

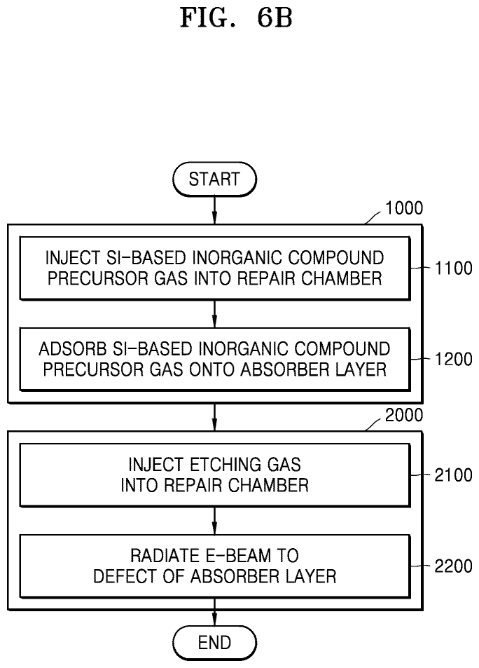

Hereinafter, by referring to FIGS. 6 to 11, a method of repairing the photomask 100 according to an embodiment is describe more specifically.

FIGS. 6A and 6B are each a flowchart illustrating a method of repairing the photomask 100 including performing Si pre-treatment on the absorber layer 140, according to an embodiment.

Referring to FIG. 6A, the method of repairing the photomask 100 according to an embodiment may include performing Si pre-treatment on the absorber layer 140 (1000) and performing absorber defect etching by using an etching gas (2000).

The performing of the Si pre-treatment on the absorber layer 140 (1000) may include injecting a Si-based inorganic compound precursor gas into a repair chamber (1100). The performing of the Si pre-treatment on the absorber layer 140 (1000) may include adsorbing the Si-based inorganic compound precursor gas onto the absorber layer 140 (1200). For example, molecules of the Si-based inorganic compound may be adsorbed onto the absorber layer 140 during the Si pre-treatment. In this regard, the Si-based inorganic compound may be a Si-based inorganic compound that may chemically react with the etching gas. Accordingly, the Si-based inorganic compound precursor gas may be properly selected according to the type of etching gas used in the absorber defect etching (2000) which is performed after the performing of the Si pre-treatment on the absorber layer (1000). The etching gas used in the performing of the absorber defect etching (2000) may include at least one of fluorine (F)-based etching gas, chlorine (Cl)-based etching gas, bromine (Br)-based etching gas, and iodine (I)-based etching gas. For example, the F-based etching gas may include at least one of XeF₂, carbon tetrafluoride (CF₄), tetrafluoroethylene (C₂F₄), carbon difluoride (C₂F₆), sulfur hexafluoride (SF₆), and nitrogen trifluoride (NF₃); however, the inventive concept is not limited thereto. The Cl-based etching gas may include or may be at least one of carbon tetrachloride (CCl₄), carbon dichloride (C₂Cl₂), chlorosilane (SiH₃Cl), boron trichloride (BCl₃), hydrogen chloride (HCl), and chlorine (Cl₂); however, the inventive concept is not limited thereto. The Br-based etching gas may include at least one of hydrogen bromide (HBr), methyl bromide (CH₃Br), and bromine (Br₂), and the I-based etching gas may include at least one of hydrogen iodide (HI), methyl iodide (CH₃I), and iodine (I₂); however, the inventive concept is not limited thereto. Accordingly, the Si-based inorganic compound may include, for example, at least one of tetraethyl orthosilicate (TEOS), tetramethyl orthosilicate (TMOS), tetrachlorosilane (SiCl₄), trichlorosilane (SiHCl₃), dichlorosilane (SiH₂Cl₂), monochlorosilane (SiH₃Cl), silane (SiH₄), and disilane (Si₂H₆).

The Si-based inorganic compound precursor gas described above may be injected into the repair chamber and adsorbed onto the surface of the absorber layer 140 without causing chemical reaction with ruthenium (Ru) on the surface of the absorber layer 140. As such, as molecules of the Si-based inorganic compound precursor gas remain adsorbed onto the surface of the absorber layer 140, an etching process using an etching gas to be injected may utilize the molecules of the Si-based inorganic compound. As such adsorption does not form a rigid layer on the surface of the absorber layer 140, after the performing of the absorber defect etching, the adsorbed molecules of Si-based inorganic compound precursor gas may be easily separated from the absorber layer by simply changing the ambient gas environment without a separate/additional process of removing the Si-based inorganic compound precursor gas.

The performing of the absorber defect etching (2000) may include injecting an etching gas into a repair chamber (2100). The performing of the absorber defect etching (2000) may include radiating an e-beam to the defect 160 of the absorber layer 140 (2200).

The etching gas injected into the repair chamber may include any gas that may chemically react with the Si-based inorganic compound precursor gas as described above. For example, the etching gas may include a F-based etching gas including at least one of XeF₂, CF₄, C₂F₄, C₂F₆, SF₆, and NF₃ and/or a Cl-based etching gas including at least one of CCl₄, C₂Cl₂, SiH₃Cl, BCl₃, HCl, and Cl₂. For example the etching gas may include XeF₂.

The etching gas listed above may cause depletion reaction with Si-based inorganic compound of the Si-based inorganic compound precursor gas adsorbed onto the surface of the absorber layer 140 and may suppress deterioration of areas of the absorber layer 140 other than the defect 160, which may be caused by F or Cl of the etching gas.

The step of radiating of the e-beam to the defect 160 of the absorber layer 140 (2200) may be a step of etching of the defect 160, which is supposed to be a normal pattern 170, by radiating an e-beam thereto under etching gas atmosphere, and may be a process of forcibly applying energy to facilitate an etching reaction. As described above, the Si-based inorganic compound precursor gas may be adsorbed onto the surface of the defect 160; however, due to the radiation of e-beam to the defect 160 of the absorber layer 140 (2200), the chemical reaction by the e-beam may be more predominant than the shielding effect of the Si-based inorganic compound precursor gas. Accordingly, even with the Si pre-treatment, the method of repairing the photomask 100 according to an embodiment may still achieve higher etching effect for the defect 160 than a method of repairing a photomask without the Si treatment and may effectively prevent deterioration of areas other than the defect 160, which indicates better etching selectivity with the Si pre-treatment than without the Si pre-treatment.

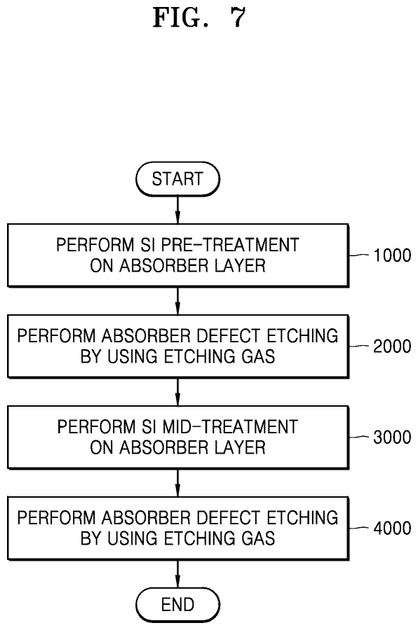

FIG. 7 is a flowchart illustrating a method of repairing the photomask 100 including performing Si pre-treatment and Si mid-treatment on the absorber layer 140, according to an embodiment.

Referring to FIG. 7, the method of repairing the photomask 100 according to an embodiment may include performing Si pre-treatment on the absorber layer 140 (1000), performing absorber defect etching by using an etching gas (2000), performing Si mid-treatment on the absorber layer 140 (3000), and performing absorber defect etching by using an etching gas (4000). The performing of the Si pre-treatment on the absorber layer 140 (1000) and the performing of the absorber defect etching by using an etching gas (2000) are substantially the same or the same as described above in relation to FIG. 6. However, the method of repairing the photomask 100 according to an embodiment may be different from the method of repairing the photomask 100 illustrated in FIG. 6 in that the performing the Si mid-treatment on the absorber layer 140 (3000) and the performing of absorber defect etching by using an etching gas (4000) are further included. Hereinafter, redundant descriptions about common steps are omitted, and steps that are additionally performed are described in detailed.

The method of repairing the photomask 100 according to an embodiment may further include, after the performing of the absorber defect etching (2000), performing the Si mid-treatment on the absorber layer 140 (3000) and performing the absorber defect etching (4000). The additional steps mentioned above are performed when it is difficult to repair defects by performing the absorber defect etching once, or it takes much time to perform the absorber defect etching due to presence of multiple defects on the photomask 100 or high difficulty of pattern formation with the absorber layer 140. As described above, in the performing of the absorber defect etching, as an etching gas that may react with the absorber layer 140 is injected into the repair chamber, when it takes much time to perform the absorber defect etching, most of the Si-based inorganic compound precursor gas adsorbed onto the absorber layer 140 during the Si pre-treatment may be consumed, and areas of the absorber layer 140 other than the defect 160 may be exposed to the etching gas. Accordingly, by additionally performing the Si mid-treatment on the absorber layer 140 after completing the performing of the absorber defect etching (2000), the shielding effect on the absorber layer 140 may be maintained, and deterioration thereof may be prevented more effectively. For example, the performing of the absorber defect etching after the Si pre-treatment may be performed for a predetermined time length, and the predetermined time length may be less than the time length during which the Si-based inorganic compound precursor gas is completely consumed.

In this regard, substantially like the Si mid-treatment process described above, the performing of the Si mid-treatment on the absorber layer 140 (3000) may include injecting a Si-based inorganic compound precursor gas into the repair chamber and adsorbing the Si-based inorganic compound precursor gas onto the absorber layer 140 (e.g., adsorbing molecules of the Si-based inorganic compound onto the absorber layer 140).

After terminating the performing of the Si mid-treatment on the absorber layer 140 (3000), the absorber defect etching may be additionally performed to carry out the repair of the defect 160, which has not been completed. The performing of the absorber defect etching (4000) may be the same as, substantially identical or similar to the performing of the absorber defect etching (2000) described above, and unlike the performing of the absorber defect etching (2000), a person skilled in the art may perform the absorber defect etching (4000) by properly adjusting the type of etching and duration of the performance according to the difficulty, target, etc. of the absorber defect etching.

Although FIG. 7 illustrates that the Si mid-treatment is performed on the absorber layer 140 (3000) only once, the absorber defect etching may be performed multiple times according to duration of the absorber defect etching and types of defects, and the Si mid-treatment may be further performed on the absorber layer 140 between the times the absorber defect etching is performed. For example, the Si mid-treatment (3000) and the absorber defect etching (4000) may be alternately performed.

The absorber defect etching may be performed multiple times when, for example, there is a difference in level in the defect, and thus the etching is performed for each level, or when the defect is so large that it is beyond the field of view (FOV), and thus the entire defect cannot be etched at a time. In such cases, the absorber defect etching may be performed multiple times, and accordingly, the Si mid-treatment may also be performed on the absorber layer 140 one time to 10 times. For example, the Si mid-treatment may be performed up to 5 times in certain embodiments.

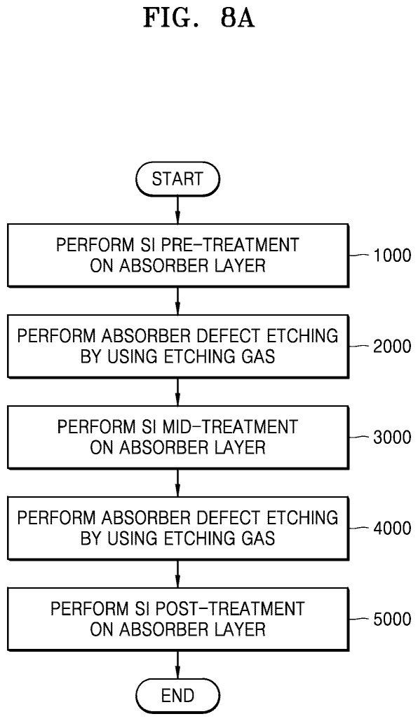

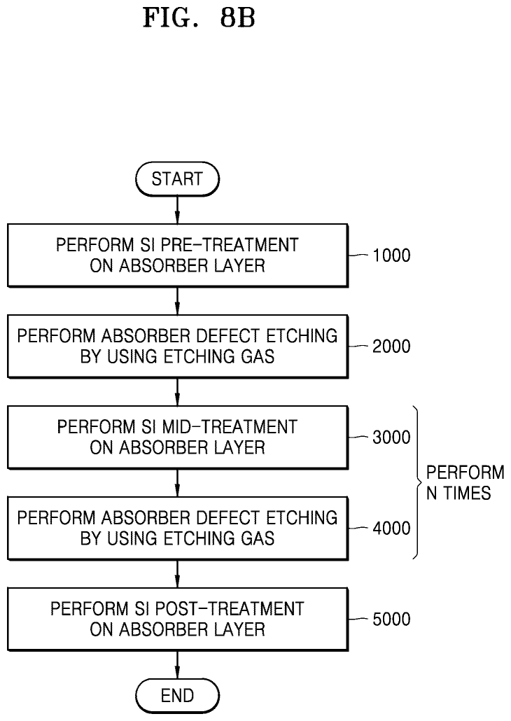

FIGS. 8A and 8B are each a flowchart illustrating a method of repairing the photomask 100 including performing the Si pre-treatment, the Si mid-treatment, and the Si post-treatment on the absorber layer 140, according to an embodiment.

Referring to FIG. 8A, the method of repairing the photomask 100 according to an embodiment may include performing the Si pre-treatment on the absorber layer 140 (1000), performing the absorber defect etching by using an etching gas (2000), performing the Si mid-treatment on the absorber layer 140 (3000), performing the absorber defect etching by using an etching gas (4000), and performing the Si post-treatment on the absorber layer 140 (5000). In this regard, the performing of the Si pre-treatment on the absorber layer 140 (1000), the performing of the absorber defect etching by using an etching gas (2000), the performing of the Si mid-treatment on the absorber layer 140 (3000), and the performing of the absorber defect etching by using an etching gas (4000) may be the same or substantially the same as described above in relation to FIG. 7. However, the method of repairing the photomask 100 according to an embodiment may be different from the method of repairing the photomask 100 illustrated in FIG. 7 in that performing the Si post-treatment on the absorber layer 140 is further included (5000).

In this regard, substantially like the Si pre-treatment and the Si mid-treatment process described above, the additional performing of the Si post-treatment on the absorber layer 140 (5000) may include injecting a Si-based inorganic compound precursor gas into the repair chamber and adsorbing the Si-based inorganic compound precursor gas onto the absorber layer 140. (e.g., adsorbing molecules of the Si-based inorganic compound onto the absorber layer 140)

The Si post-treatment may be further performed on the absorber layer 140 to protect the absorber layer 140 from the remaining etching gas in the repair chamber after the absorber defect etching is performed (4000). In this manner, reaction the etching gas and normal patterns of the absorber layer 140 may be avoided until the method of repairing the photomask 100 is completed, and a high-quality photomask that is repaired at a high precision level may be obtained.

Referring to FIG. 8B, the method of repairing the photomask 100 according to an embodiment, which includes performing the Si pre-treatment, the Si mid-treatment, and the Si post-treatment on the absorber layer 140, may include performing the Si mid-treatment on the absorber layer 140 (3000) and performing the absorber defect etching (4000) one or more times (n times. As described above, this is to repair photomask 100 by stages according to the duration of the absorber defect etching, various types of defects, such as stepped defect, etc., the size of the defect, etc., and n may be about 1 to 10 or not more than 5.

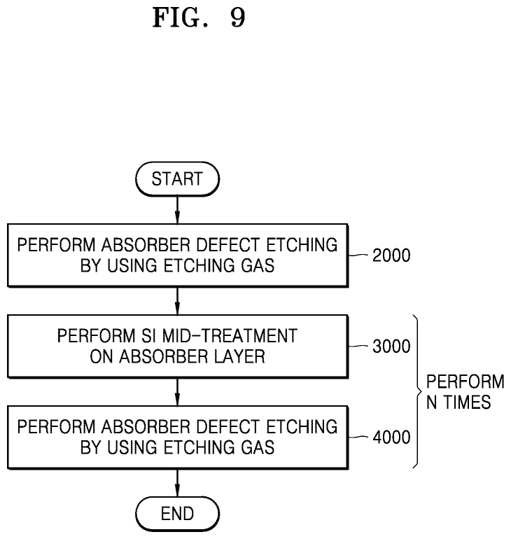

FIG. 9 is a flowchart illustrating a method of repairing the photomask 100 including performing the Si mid-treatment on the absorber layer 140, according to an embodiment.

Referring to FIG. 9, the method of repairing the photomask 100 according to an embodiment may include performing the absorber defect etching by using an etching gas (2000), performing the Si mid-treatment on the absorber layer 140 (3000), and performing the absorber defect etching by using an etching gas (4000). In this regard, the performing of the Si mid-treatment on the absorber layer 140 (3000) and the performing of the absorber defect etching by using an etching gas (4000) may be carried out n times, wherein n may be 1 to 10 or not more than 5.

The method of repairing the photomask 100 according to an embodiment illustrated in FIG. 9 may be different from the method illustrated in FIG. 7 in that the performing of the Si pre-treatment on the absorber layer 140 (1000) is not included.

The method of repairing the photomask 100 according to an embodiment may generally include the performing of the Si pre-treatment as illustrated in FIG. 7 to achieve the shielding effect of the Si-based inorganic compound precursor gas for the absorber layer 140; however, as the process conditions for the steps in which the absorber defect etching is performed (2000 and 4000) may be different from each other according to the target of the absorber defect etching, types of etching gas, etc., a person skilled in the art may only perform the Si mid-treatment between the steps in which the absorber defect etching is performed (2000 and 4000) without performing the Si pre-treatment on the absorber layer 140. For example, in certain embodiments, the method of repairing a photomask 100 may not include the Si pre-treatment on the absorb layer 140 and include the Si mid-treatment performed between absorber defect etching steps.

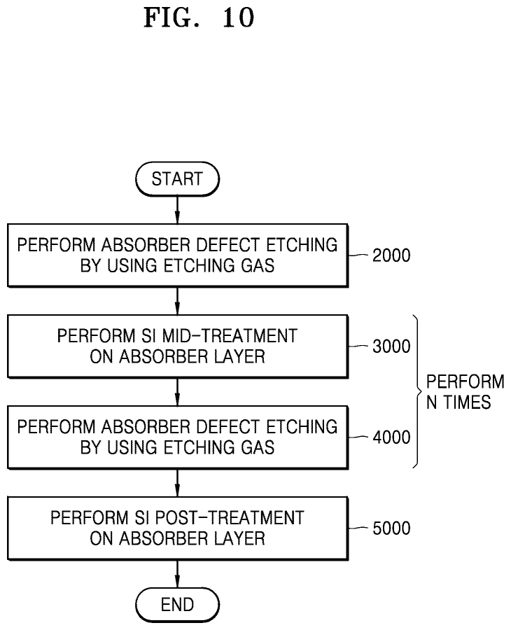

FIG. 10 is a flowchart illustrating a method of repairing the photomask 100 including performing the Si mid-treatment and the Si post-treatment on the absorber layer 140, according to an embodiment.

Referring to FIG. 10, the method of repairing the photomask 100 according to an embodiment may include performing the absorber defect etching by using an etching gas (2000), performing the Si mid-treatment on the absorber layer 140 (3000), performing the absorber defect etching by using an etching gas (4000), and performing the Si post-treatment on the absorber layer 140 (5000). In this regard, the performing of the Si mid-treatment on the absorber layer 140 (3000) and the performing of the absorber defect etching by using an etching gas (4000) may be carried out n times, wherein n may be 1 to 10 or not more than 5.

The performing of the absorber defect etching by using an etching gas (2000), the performing of the Si mid-treatment on the absorber layer 140 (3000), and performing of the absorber defect etching by using an etching gas (4000) may be the same or substantially the same as described above in relation to FIG. 9. However, the method of repairing the photomask 100 according to an embodiment may be different from the method of repairing the photomask 100 illustrated in FIG. 9 in that performing the Si post-treatment on the absorber layer 140 is further included (5000).

The Si post-treatment may be performed on the absorber layer 140 (5000) to protect the absorber layer 140 from the remaining etching gas in the repair chamber after the last absorber defect etching is performed (4000). Accordingly, compared to the method of repairing the photomask 100 including performing only the Si mid-treatment on the absorber layer 140, the method of repairing the photomask 100 including performing both of the Si mid-treatment and the Si post-treatment may obtain a high-quality repaired photomask. For example, the Si post-treatment may be beneficial to a high-quality photomask.

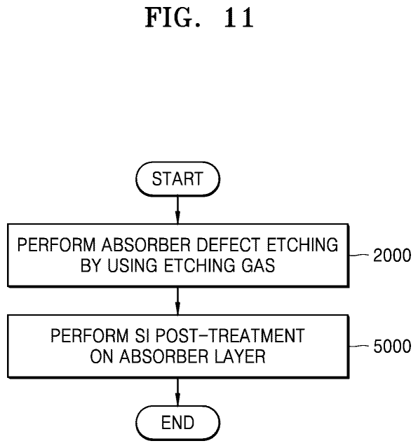

FIG. 11 is a flowchart illustrating a method of repairing the photomask 100 including performing the Si post-treatment on an absorber layer, according to an embodiment.

Referring to FIG. 11, the method of repairing the photomask 100 according to an embodiment may include performing the absorber defect etching by using an etching gas (2000) and performing the Si post-treatment on the absorber layer 140 (5000). The performing of the absorber defect etching by using an etching gas (2000) and the performing of the Si post-treatment on the absorber layer 140 (5000) may be the same or substantially the same as described above. The method of repairing the photomask 100 according to an embodiment illustrated in FIG. 11 may be different from the method illustrated in FIG. 10 in that the performing of the Si mid-treatment on the absorber layer 140 (3000) is not included.

The method of repairing the photomask 100 according to an embodiment may include the performing of the Si pre-treatment or the Si mid-treatment to achieve the shielding effect of the Si-based inorganic compound precursor gas for the absorber layer 140; however, as the process conditions for the step in which the absorber defect etching is performed (2000) may be different from each other according to the types of etching gas, etc., a person skilled in the art may only perform the Si post-treatment on the absorber layer 140 after the absorber defect etching without performing the Si pre-treatment and the Si mid-treatment on the absorber layer 140.

### Examples

### 1) Example 1

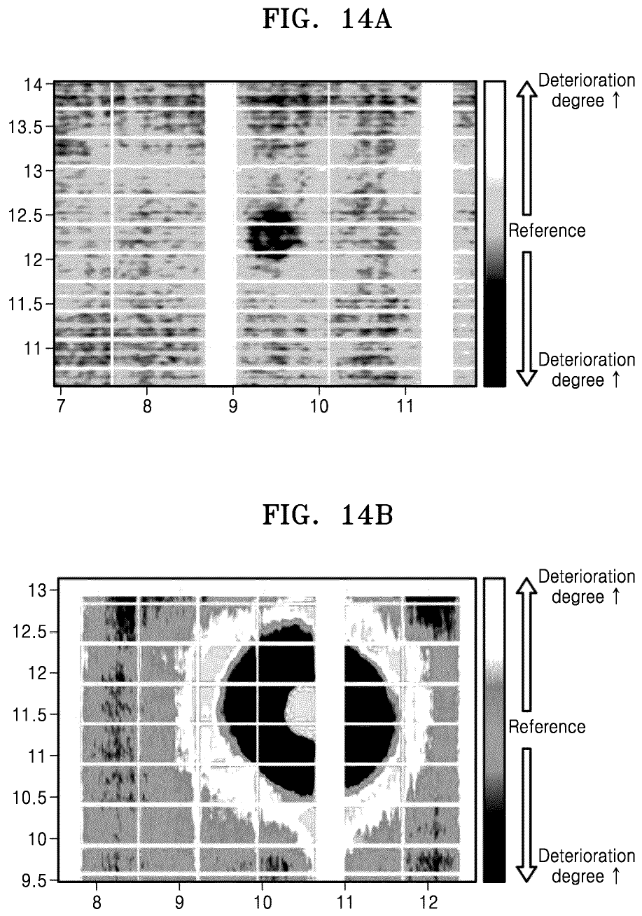

First, the photomask 100 including the absorber layer 140 having at least one defect 160 was prepared. By injecting TEOS into the repair chamber, the Si pre-treatment was performed on the absorber layer 140 of the photomask 100. Then, an e-beam was radiated to the defect 160 of the photomask 100 while XeF₂ and H₂O was injected into the repair chamber. The CD uniformity inspection was conducted by using the photomask 100 thus obtained, and the results thereof are shown in FIG. 14A.

### 2) Comparative Example 1

The photomask was obtained by using the same method as in Example 1, except that the process of injecting TEOS into the repair chamber is omitted, thereby omitting the Si pre-treatment. The CD uniformity inspection was conducted by using the obtained mask, and the result thereof are shown in FIG. 14B.

As a result, as shown in FIGS. 14A and 14B, the gas damage of Intensity 10 % or greater was caused widely in Comparative Example 1 which did not include the Si pre-treatment, whereas the gas damage less than Intensity 1 % was caused in a relatively narrow range or in relatively small area in Example 1. It was found that the degree and range of deterioration decreased significantly in the photomask of Example 1, compared to Comparative Example 1. For example, FIG. 14A shows relatively uniform CD throughout the picture, and FIG. 14B shows that CD distribution is not uniform throughout the picture.

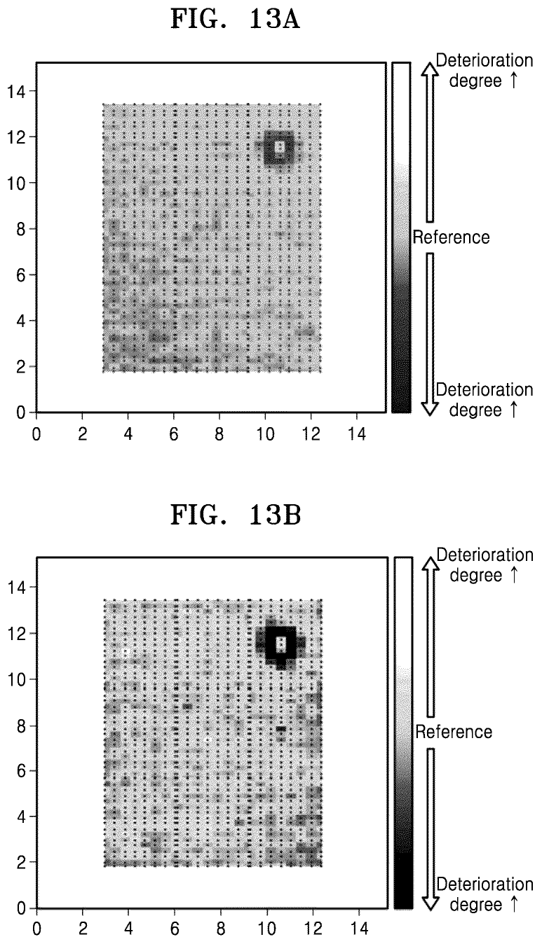

FIGS. 13A and 13B each illustrate a wafer CD uniformity map when a method of repairing a photomask is performed without Si treatment. Referring to the results of FIGS. 13A and 13B due to the deterioration of the photomask that may be caused when the Si treatment is not performed, the CD defect may be found on the wafer patterned from the photomask.

Thus, through the experiments, it is confirmed that performing the Si treatment on the absorber layer 140 of the photomask 100 is effective for preventing the deterioration of areas of the absorber layer 140 of the photomask 100, other than the defect 160, and the method of repairing the photomask 100 according to an embodiment may contribute to high-quality photomask 100 without defects and to the manufacture and high yield of wafers.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A method of repairing a photomask, the method comprising:
performing silicon (Si) pre-treatment on an absorber layer having a defect; and
performing absorber defect etching by using an etching gas.

2. The method of claim 1, wherein the performing of the Si pre-treatment on the absorber layer comprises:
injecting a precursor gas of a Si-based inorganic compound into a repair chamber; and
adsorbing molecules of the Si-based inorganic compound onto the absorber layer.

3. The method of claim 2, wherein the Si-based inorganic compound comprises at least one of tetraethyl orthosilicate (TEOS), tetramethyl orthosilicate (TMOS), tetrachlorosilane (SiCl₄), trichlorosilane (SiHCl₃), dichlorosilane (SiH₂Cl₂), monochlorosilane (SiH₃Cl), silane (SiH₄), and disilane (Si₂H₆).

4. The method of claim 1, wherein the performing of the absorber defect etching by using an etching gas comprises:
injecting the etching gas into a repair chamber; and
radiating an e-beam to the defect of the absorber layer.

5. The method of claim 1, further comprising
alternately performing Si mid-treatment on the absorber layer and absorber defect etching such that a total number of the absorber defect etching is 2 times to 10 times and each Si mid-treatment is performed between two consecutive absorber defect etchings.

6. The method of claim 5, further comprising performing Si post-treatment on the absorber layer after a last time of the absorber defect etching is performed.

7. The method of claim 1, further comprising performing Si post-treatment on the absorber layer after the absorber defect etching is performed.

8. A method of repairing a photomask, the method comprising:
alternately performing absorber defect etching by using an etching gas and Si mid-treatment on an absorber layer such that a total number of the absorber defect etching is 2 times to 10 times and each Si mid-treatment is performed between two consecutive absorber defect etchings.

9. The method of claim 8, further comprising performing Si post-treatment on the absorber layer after a last time of the absorber defect etching is performed.

10. The method of claim 9, further comprising performing Si pre-treatment on the absorber layer before a first absorber defect etching is performed.

11. The method of claim 10, wherein the photomask include a substrate, a reflective layer, a capping layer, and an absorber layer, and
wherein the reflective layer, the capping layer, and the absorber layer are sequentially stacked on the substrate.

12. The method of claim 8, further comprising performing Si pre-treatment on the absorber layer before a first absorber defect etching is performed.

13. The method of claim 12, wherein the photomask include a substrate, a reflective layer, a capping layer, and an absorber layer, and
wherein the reflective layer, the capping layer, and the absorber layer are sequentially stacked on the substrate and the absorber layer includes at least one defect before repairing the photomask.

14. A method of repairing a photomask, the method comprising:
performing absorber defect etching by using an etching gas; and
performing Si post-treatment on an absorber layer.

15. The method of claim 14, wherein the photomask include a substrate, a reflective layer, a capping layer, and an absorber layer, and
wherein the reflective layer, the capping layer, and the absorber layer are sequentially stacked on the substrate and the absorber layer includes at least one defect before repairing the photomask.
